(19) United States
(12) Patent Application Publication
(10) Pub. No.: US 2024/0234394 A1
(43) Pub. Date: Jul. 11, 2024

(54) LIGHT-EMITTING DEVICE, BULB, AND MANUFACTURING PROCESS THEREOF

(71) Applicant: LONGYAN DEYU LIGHTING CO., LTD., Longyan City (CN)

(72) Inventors: Zunxiang Huang, Longyan City (CN); Yuanming Li, Longyan City (CN); Dehua Huang, Longyan City (CN)

(21) Appl. No.: 18/232,374

(22) Filed: Aug. 10, 2023

(30) Foreign Application Priority Data
Jan. 10, 2023 (CN) 202310030469.9
Jan. 10, 2023 (CN) 202320061735.X

(51) Int. Cl. H01L 25/16; H01L 25/075; H01L 33/50; H01L 33/62

(52) U.S. Cl. CPC H01L 25/167; H01L 25/0753; H01L 33/507; H01L 33/62; F21K 9/232; H01L 2933/0066

(57) ABSTRACT

A light-emitting device, a bulb and a manufacturing process thereof are disclosed. The light-emitting device includes a substrate, on which a conductive line, a control bare die, a light-emitting bare die and a wiring terminal are arranged. The conductive line is electrically connected with the control bare die and/or the wiring terminal and/or the light-emitting bare die. The control bare die is configured to control the switch and/or current of the light-emitting bare die, and the wiring terminal is externally connected with a power supply; the present disclosure reduces the volume, expands the applicable scene and reduces the cost by optimizing the layout of the substrate, the conductive line, the control bare die, the light-emitting bare die and the wiring terminal, and setting the slender substrate.

### TECHNICAL FIELD

The present disclosure relates to lighting technology, in particular to a light-emitting device, a bulb and a manufacturing process thereof.

### BACKGROUND

The light-emitting device is a device that converts electric energy into light energy.

In recent years, LED has been widely used in traffic signal light, large area display screen, building decoration and other lighting fields due to its advantages of energy conservation and environmental protection. With the wide application of LED, there puts forward more demands on its flickering and control methods. For example, various festival atmosphere lights and command lights need more flickering to change the scenes to incite the atmosphere.

However, in the traditional light string flashing mode in which LED is used as the light source of the light-emitting device at present, many monochrome light strings flash synchronously in a whole string. And the corresponding light-emitting device has too large volume, less applicable scenarios, poor reliability and high cost.

Moreover, in order to achieve the luminous effects such as meteor light, color illusion, flicker etc., the existing light-emitting device will place the separately packaged control component and luminous component on PCB, aluminum substrate or other circuit boards by means of surface mounting, and achieve the effects of color illusion, flicker, etc. through the control of the control component. In this technology solution, the control chip and the luminous chip need to be packaged separately through the packaging process, and then assembled on the circuit board.

At the same time, due to the large size of the component after packaging, for example, a control component packaged with SOP8 is 6.2 mm long and 5.1 mm wide, in addition to several packaged luminous components, the circuit board used to assemble the two packaged components needs a relatively large size, and cannot obtain a smaller light-emitting device, which is not suitable for the application of products such as filament.

Therefore, a new light-emitting device is an urgent problem to be studied.

The above information disclosed in this part is only used to understand the background of the inventive concept of this disclosure. Therefore, the above information may include information that does not constitute the prior art.

### SUMMARY

The object of the present disclosure is to provide a light-emitting device to overcome the above defects, optimize the layout of components through continuous experiments, reduce the volume, expand the applicable scene, enhance the reliability and reduce the cost.

To achieve the above object, the solution of the present disclosure is: the light-emitting device, including a substrate, wherein a conductive line, a control bare die, a light-emitting bare die and a wiring terminal are arranged on the substrate; the conductive line is electrically connected with the control bare die and/or the wiring terminal and/or the light-emitting bare die; the control bare die is used to control the switch and/or current of the light-emitting bare die; and the wiring terminal is externally connected with a power supply.

Further, the substrate is a slender substrate with a length of a≥20 mm, a width of b≤5 mm, and a length-width ratio of a/b≥5, so as to obtain a thinner light-emitting device and apply it to bulb products.

Further, the control bare die is a MCU bare die or a decoding bare die. The MCU bare die is preset with corresponding control program, and the MCU bare die directly controls the light-emitting bare die to obtain preset luminous effect. The decoding bare die is configured to receive and decode the external control signal, reshape and decode the control signal, and then transmit it to the light-emitting bare die to control the light-emitting bare die.

Further, a current limiting resistor is also connected in series between the control bare die and the wiring terminal and/or between the control bare die and the light-emitting bare die to limit the current input to the light-emitting bare die and play the role of protecting the light-emitting bare die.

Further, the light-emitting bare die is connected with a zener diode to limit the voltage input to the light-emitting bare die and play the role of protecting the light-emitting bare die.

Further, the light-emitting bare die can select monochrome bare die and/or polychrome bare die according to the desired luminous effect.

Further, the substrate is also coated with a transparent medium layer and/or a transparent medium layer containing phosphor powder, and the transparent medium layer is used to protect the components on the substrate. The transparent medium layer containing phosphor powder can realize the conversion of luminous effect at the same time. Some part is coated with a transparent medium layer, and the rest part is coated with a transparent medium layer containing phosphor powder, so as to realize the luminous color conversion of some part of the light-emitting bare dies, while retaining the luminous color of part of the light-emitting bare dies.

Further, the conductive line is a silver paste conductive line with good conductive effect.

Further, the substrate is a transparent substrate made of ceramics, sapphire, glass and other materials, so as to obtain a 360-degree all-round luminous effect.

The present disclosure also provides a bulb, which includes the light-emitting device mentioned above.

Also a manufacturing process of the light-emitting device is provided, the manufacturing process includes the following steps:
1) Wiring: arranging conductive lines and wiring terminals on the substrate;
2) Die bonding: placing the control bare die and the light-emitting bare die on the substrate;
3) Welding wire: connecting the control bare die and the light-emitting bare die to the conductive line and the wiring terminal.

Further, the substrate in step 1) is the transparent substrate.

Further, the conductive line set in step 1) is formed by printing silver paste on the substrate and then sintering.

Further, the specification of the substrate in step 1): the length of the substrate a≥20 mm, the width of the substrate b≤5 mm, and the length-width ratio a/b≥5.

Further, the step 2) die bond also includes: placing the current limiting resistor on the substrate; the step 3) welding wire also includes: connecting the current limiting resistor to the conductive line and wiring terminal and/or connecting the current limiting resistor to the control bare die and the light-emitting bare die.

Further, the step 2) die bond further includes: placing the zener diode on a substrate; the welding wire in step 3) also includes: connecting the zener diode to the conductive line.

Further, the control bare die is the decoding bare die or the MCU bare die.

Further, the light-emitting bare die is the monochrome bare die or the polychrome bare die.

Further, the manufacturing process also includes:
4) Gluing: the transparent medium layer and/or the transparent medium layer containing phosphor powder are coated on the light-emitting device obtained in step 3).

After adopting the above solution, the present disclosure has the following advantageous effects:
(1) The light-emitting device of the present disclosure can reduce the volume, expand the applicable scene and reduce the cost by optimizing the layout of the substrate, the conductive lines, the control bare die, the light-emitting bare die and the wiring terminal, and setting the slender substrate.
(2) The light-emitting device of the present disclosure uses MCU bare die or decoding bare die to facilitate preset luminous effect or control luminous effect.
(3) The light-emitting device of the present disclosure uses a current limiting resistor and a zener diode to protect the components and enhances the reliability.
(4) The light-emitting device of the present disclosure is used to protect the components on the substrate and realize the conversion of luminous color by covering a transparent medium layer or a transparent medium layer containing phosphor powder.
(5) The light-emitting device of the present disclosure uses the monochrome bare die, the polychrome bare die, the transparent substrate and the silver paste conductive line to obtain good luminous effect and conductive effect.
(6) The bulb of the present disclosure which adopts the light-emitting device described above, has small volume and is widely used in various scenes.
(7) The present disclosure provides an effective manufacturing process for obtaining a thinner light-emitting device, thereby reducing the manufacturing cost.
(8) The manufacturing process provided by the present disclosure makes slender setting on the substrate through wiring, die bonding, welding wire and gluing, so as to optimize the layout of the substrate, the conductive line, the control bare die, the light-emitting bare die and the wiring terminal, reduce the volume and expand the applicable scene.
(9) The manufacturing process provided by the present disclosure uses sintered printing silver paste to obtain a conductive line with excellent performance.
(10) The manufacturing process provided by the present disclosure is used to protect the components on the substrate and realize the conversion of the luminous effect by coating the transparent medium layer or the transparent medium layer containing phosphor powder.

### BRIEF DESCRIPTION OF THE DRAWINGS

FIG. 1 is a schematic diagram of the section structure from the front side of a light-emitting device of the present disclosure;

FIG. 2 is another structure diagram of the section structure from the front side of the light-emitting device of the present disclosure;

FIG. 3 is a schematic diagram of the section structure from one side of the light-emitting device of the present disclosure;

FIG. 4 is a schematic diagram of the section structure from the other side of the light-emitting device of the present disclosure;

FIG. 5 is a flow chart of the manufacturing process of the light-emitting device of the present disclosure;

FIG. 6 is a schematic diagram of the section structure from the front side of the Embodiment 1 of the present disclosure;

FIG. 7 is an enlarged view of part A of the section structure from the front side of the Embodiment 1 of the present disclosure;

FIG. 8 is an enlarged view of part B of the section structure from the front side of the Embodiment 1 of the present disclosure;

FIG. 9 is a schematic diagram of the section structure from the front side of the Embodiment 2 of the present disclosure;

FIG. 10 is an enlarged view of part C of the section structure from the front side of the Embodiment 2 of the present disclosure;

FIG. 11 is an enlarged view of part D of the section structure from the front side of the Embodiment 2 of the present disclosure; and

FIG. 12 is a structural diagram of a bulb of the present disclosure.

### DETAILED DESCRIPTION OF THE EMBODIMENTS

The present disclosure is further described in detail below in combination with the drawings and specific embodiments.

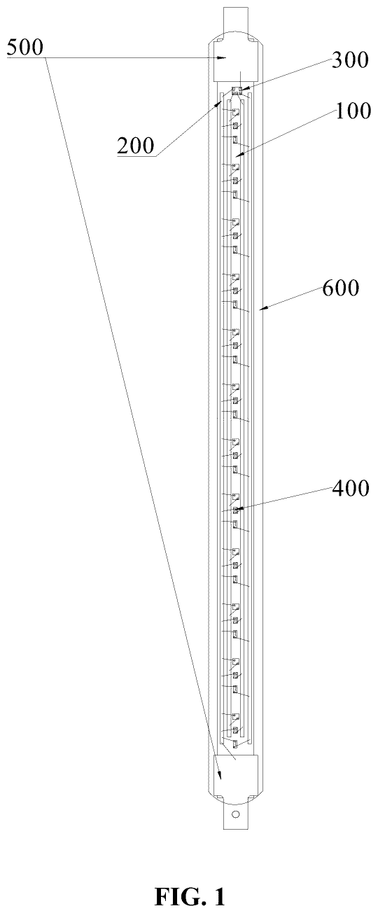

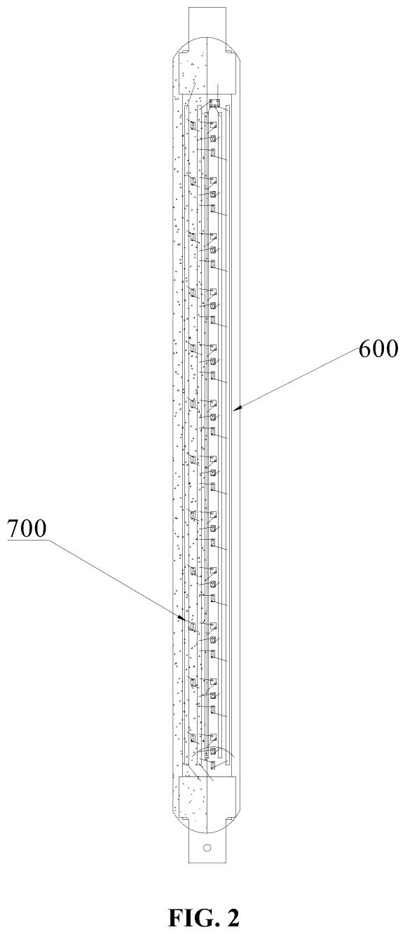

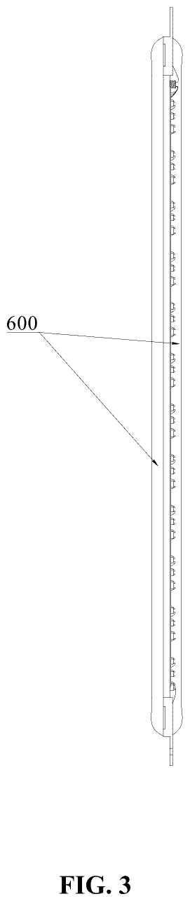

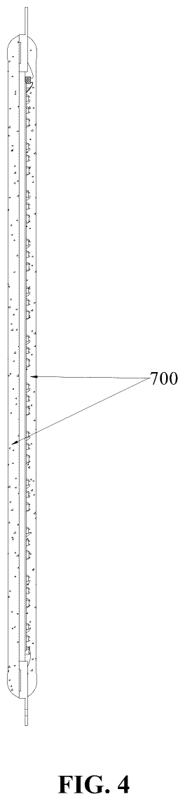

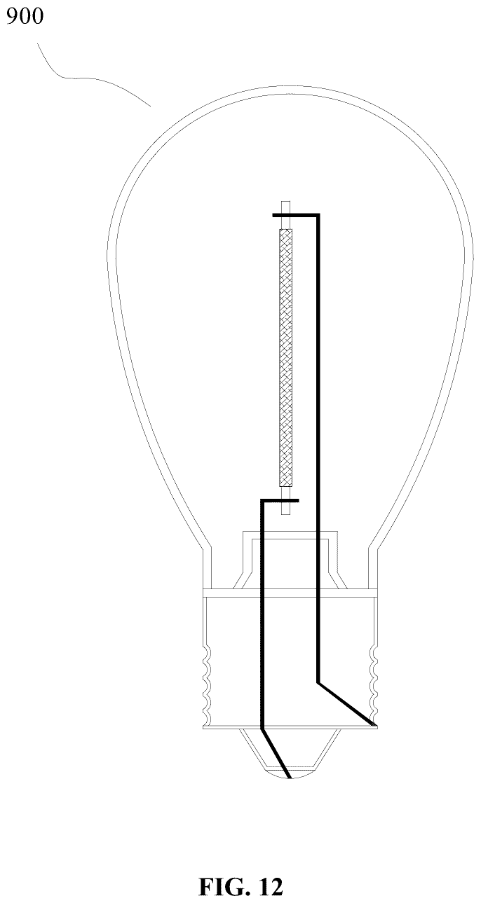

The present disclosure provides a light-emitting device, referring to FIGS. 1-4 and 12, including a substrate 100. Wherein a conductive line 200, a control bare die 300, a light-emitting bare die 400 and a wiring terminal 500 are arranged on the substrate 100. The conductive line 200 is electrically connected with the control bare die 300 and/or the wiring terminal 500 and/or the light-emitting bare die 400. The control bare die 300 is used to control the switch and/or current of the light-emitting bare die 400, the wiring terminal 500 is externally connected with the power supply.

Specifically, the substrate 100 is a slender substrate. The substrate length a≥20 mm, the substrate width b≤5 mm, and the length-width ratio a/b≥5, so as to obtain a thinner light-emitting device and apply it to bulb products.

Specifically, the control bare die 300 is a MCU bare die or a decoding bare die, the MCU bare die is preset with a corresponding control program, and the MCU bare die directly controls the light-emitting bare die 400 to obtain preset luminous effect. The decoding bare die is used to receive and decode the external control signal, reshape and decode the control signal, and then transmit it to the light-emitting bare die 400, so as to control the light-emitting bare die 400.

Specifically, a current limiting resistor is also connected in series between the control bare die 300 and the wiring terminal 500 and/or between the control bare die 300 and the light-emitting bare die 400 to limit the current input to the light-emitting bare die 400 for protecting the light-emitting bare die 400.

Specifically, the light-emitting bare die 400 is connected with a zener diode to limit the voltage input to the light-emitting bare die 400 for protecting the light-emitting bare die 400.

Specifically, the light-emitting bare die 400 can select monochrome bare die and/or polychrome bare die according to the desired luminous effect.

Specifically, the substrate 100 is also coated with a transparent medium layer 600 and/or a transparent medium layer 700 containing phosphor powder. The transparent medium layer 600 is used to protect the components on the substrate 100. The transparent medium layer 700 containing phosphor powder can also realize the conversion of the luminous effect at the same time. Some part of the substrate 100 is coated with the transparent medium layer 600, and the rest part of the substrate 100 is coated with the transparent medium layer containing phosphor powder, so as to realize the conversion of the luminous color of some part of the light-emitting bare dies 400, while retaining the luminous color of the rest part of the light-emitting bare dies.

Specifically, the conductive line 200 is a silver paste conductive line with good conductive effect.

Specifically, the substrate 100 is a transparent substrate made of ceramics, sapphire, glass and other materials, so as to obtain a 360-degree all-round luminous effect.

Specifically, a bulb 900 is also provided, including the above light-emitting device.

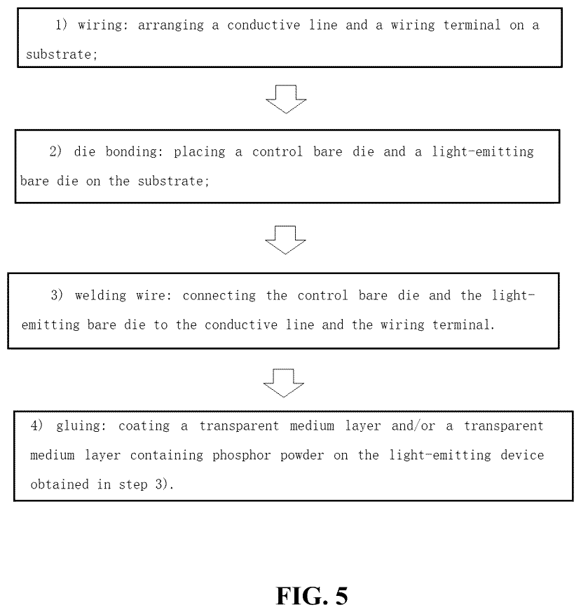

The present disclosure provides a manufacturing process of the light-emitting device. Referring to FIGS. 1-5, the manufacturing process includes:
1) Wiring: arranging the conductive line 200 and the wiring terminal 500 on the substrate 100;
2) Die bonding: placing the control bare die 300 and the light-emitting bare die 400 on the substrate 100;
3) Welding wire: connecting the control bare die 300 and the light-emitting bare die 400 to the conductive line 200 and the wiring terminal 500.

Specifically, step 1) the substrate 100 is a transparent substrate.

Specifically, step 1) the conductive line 200 is formed by printing silver paste on the substrate and then sintering.

Specifically, the specification of the substrate in step 1): the substrate length a≥20 mm, the substrate width b≤5 mm, and the length-width ratio a/b≥5.

Specifically, the step 2) die bonding also includes: placing the current limiting resistor on the substrate; the step 3) welding wire also includes: connecting the current limiting resistor to the conductive line and the wiring terminal and/or connecting the current limiting resistor to the control bare die and the light-emitting bare die.

Specifically, the step 2) die bonding also includes: placing the zener diode on the substrate; the welding wire in step 3) also includes: connecting the zener diode to the conductive line.

Specifically, the control bare die 300 is the decoding bare die or the MCU bare die.

Specifically, the light-emitting bare die 400 is the monochrome bare die or the polychrome bare die.

Specifically, the manufacturing process also includes:
4) Gluing: the transparent medium layer 600 and/or the transparent medium layer containing phosphor powder 700 are coated on the light-emitting device obtained in step 3).

### Embodiment 1

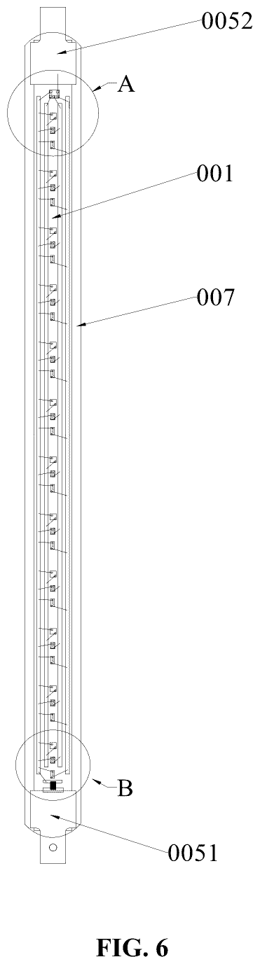

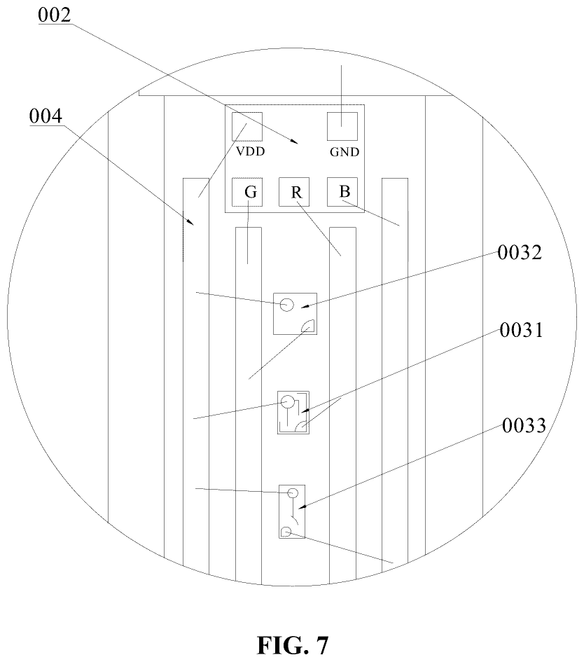

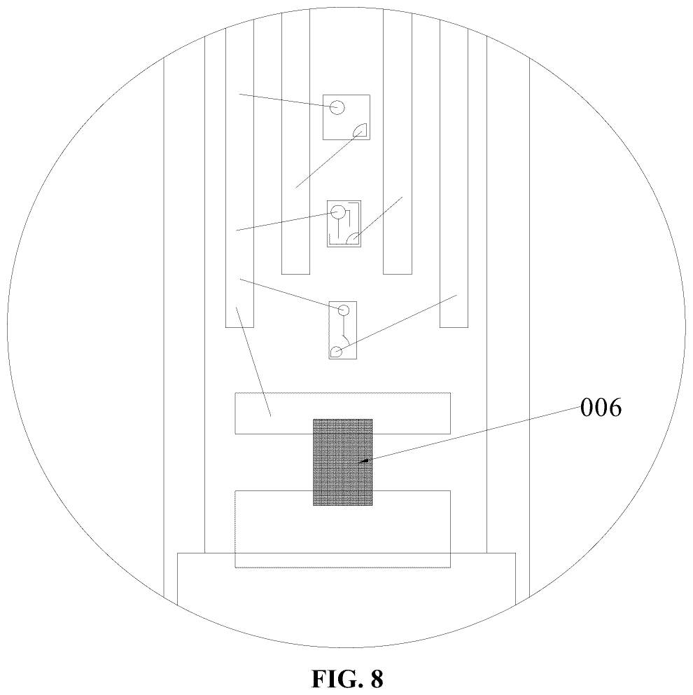

Referring to FIGS. 6-8, it is an embodiment of the light-emitting device of the present disclosure, including a substrate 001, a decoding bare die 002, several red LED bare dies 0031, a green LED bare die 0032, a blue LED bare die 0033, a silver paste conductive line 004, a positive wiring terminal 0051, a negative wiring terminal 0052, a current limiting resistor 006, and a transparent medium layer 007.

In this embodiment, the substrate 001 is an elongated ceramic substrate with a length a of 33 mm, a width b of 1.5 mm and a length-width ratio: a/b=22. The substrate 001 is provided with silver paste conductive line 004, and both ends of the substrate 001 are provided with the positive wiring terminal 0051 and the negative wiring terminal 0052. The decoding bare die 002 and several red LED bare dies 0031, the green LED bare die 0032 and the blue LED bare die 0033 are fixed on the substrate 001. Through the silver paste conductive line 004, the VDD end of the decoding bare die 002 is connected to the positive wiring terminal 0051, and the GND end of the decoding bare die 002 is connected to the negative wiring terminal 0052. The positive pole of the red LED bare die 0031, the green LED bare die 0032 and the blue LED bare die 0033 are connected to the positive wiring terminal 0051 through the silver paste conductive line 004. The negative pole of the red LED bare die 0031, the green LED bare die 0032 and the blue LED bare die 0033 are respectively connected to the R, G and B three ports on the decoding bare die 002. A current limiting resistor 006 is connected in series between the decoding bare die 002, the red LED bare die 0031, the green LED bare die 0032, the blue LED bare die 0033 and the positive wiring terminal 0051 through silver paste conductive line 004 to limit the current input to the light-emitting bare die and protect the light-emitting bare die. Finally, the transparent medium layer 007 is coated on the periphery of the substrate 001 to protect the substrate 001, the decoding bare die 002, the red LED bare die 0031, the green LED bare die 0032, the blue LED bare die 0033 and the silver paste conductive line 004 on the substrate.

In this embodiment, the decoding bare die 002 is selected to receive and decode the external control signal, reshape and decode the external control signal, and then transmit it to the monochrome bare die to manage the current and the switch status of the monochrome bare die, so that the light-emitting device can realize the complex flicker function.

### Embodiment 2

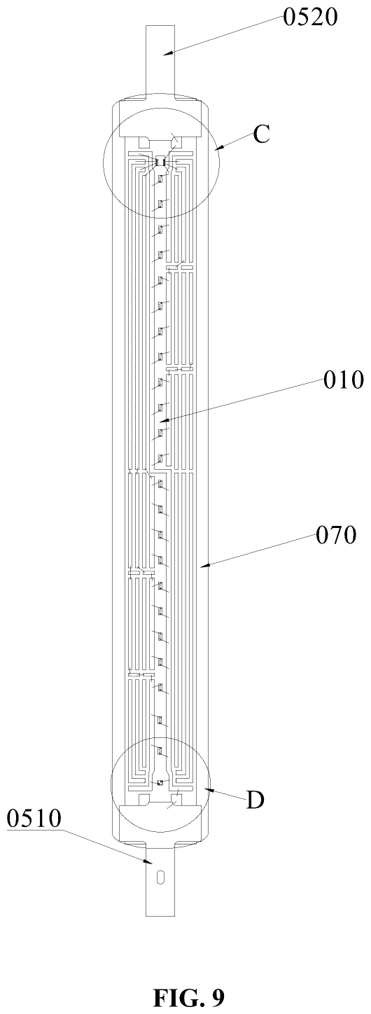

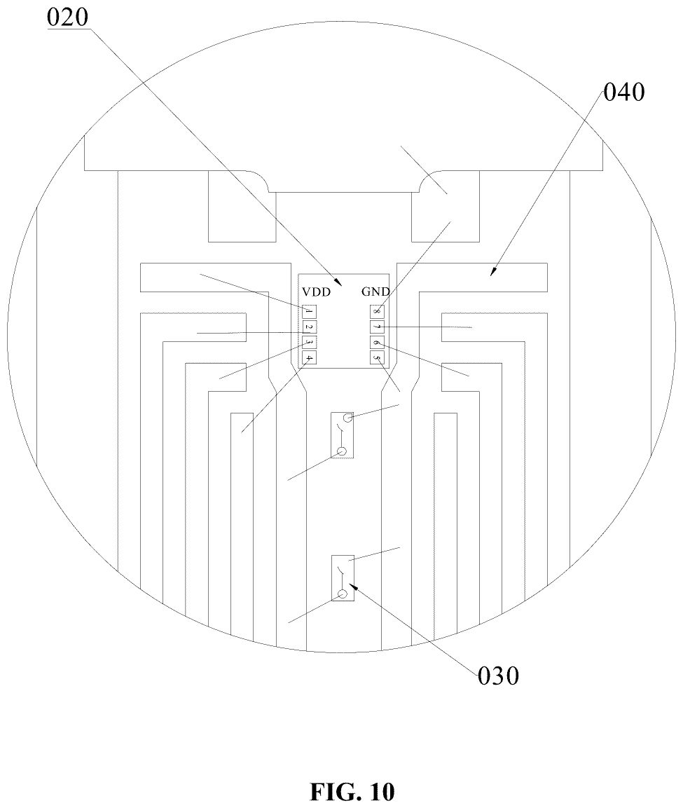

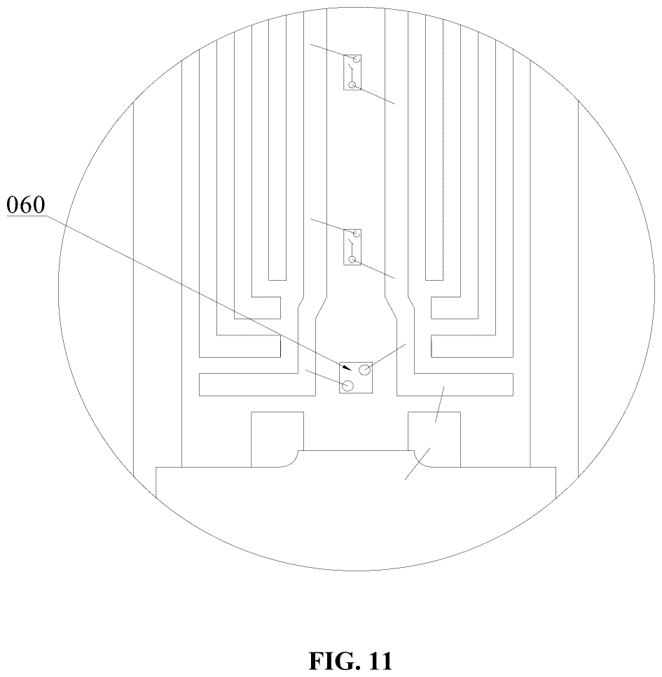

Referring to FIGS. 9-11, it is another embodiment of the light-emitting device of the present disclosure, including a substrate 010, a MCU bare die 020, several blue LED bare dies 030, a conductive line 040, a positive wiring terminal 0510, a negative wiring terminal 0520, a zener diode 060, and a transparent medium layer 070 of phosphor powder.

In this embodiment, the substrate 010 is an elongated ceramic substrate with a length a of 45 mm, a width b of 3 mm and a length-width ratio a/b=15. The substrate 010 is provided with a conductive line 040, and the positive wiring terminal 0510 and the negative wiring terminal 0520 are arranged at both ends of the substrate 010. The MCU bare die 020 and several blue LED bare dies 030 are on the substrate 010. The conductive line 040 connects the positive pole (port 1) of the MCU bare die 020 to the positive wiring terminal 0510, and the negative pole (port 8) of the MCU bare die 020 to the negative wiring terminal 0520. Several groups of blue LED bare dies 030 are divided into six groups. The conductive line 040 connects to the positive pole of several blue LED bare dies 030 to the positive wiring terminal, and the negative pole is connected to ports 2-7 on the MCU bare die 020 respectively. The zener diode 060 is connected in parallel at both ends of the blue LED bare die 030 through the conductive line 040. Finally, a transparent medium layer 070 containing phosphor powder is also coated on the periphery of the substrate 010 to protect the circuit elements on the substrate 010 and realize the conversion of luminous effects.

In this embodiment, the selected control bare die is a kind of MCU bare die with a preset control program. The MCU bare die transmits the preset control mode to each group of blue LED bare dies, manages the current and the switch status of each group of blue LED bare dies, and enables the light-emitting device to realize the functions of light beating and flashing.

The light-emitting device of the present disclosure can reduce the volume, expand the applicable scene and reduce the cost by optimizing the layout of the substrate, the conductive line, the control bare die, the light-emitting bare die and the wiring terminal, and setting the slender substrate; the use of MCU bare die or decoding bare die is convenient for preset luminous effect or controlling luminous effect; the current limiting resistor and the zener diode are used to protect the components and enhance the reliability; the transparent medium layer or the transparent medium layer containing phosphor powder is coated to protect the components on the substrate and realize the conversion of luminous color; the use of the monochrome bare die, the polychrome bare die, the transparent substrate and the silver paste conductive line can achieve good luminous effect and conductive effect. The bulb of the present disclosure adopts the light-emitting device, which has small volume and wide application scenes. The present disclosure provides a manufacturing process for effectively obtaining a thinner light-emitting device, thereby reducing the manufacturing cost; the manufacturing process carries out slender settings for the substrate through wiring, die bonding, welding wire and gluing, optimizes the layout of the substrate, the conductive line, the control bare die, the light-emitting bare die and the wiring terminal, so as to reduce the volume and expand the applicable scenarios. The sintered printing silver paste is used to obtain conductive line with excellent performance. The transparent medium layer or the transparent medium layer containing phosphor powder is used to protect the components on the substrate and realize the conversion of the luminous effect.

The basic principles, main features and advantages of the present disclosure are shown and described above. Technicians in the industry should understand that the present disclosure is not limited by the above embodiments, and what is described in the above embodiments and specifications is only to explain the principle of the present disclosure. Without departing from the spirit and scope of the present disclosure, the present disclosure will also have various changes and improvements, which fall within the scope of the present disclosure required to be protected. The scope of protection claimed by the present disclosure is defined by the appended claims and their equivalents.

1. A light-emitting device, comprising a substrate, wherein a conductive line, a control bare die, a light-emitting bare die and a wiring terminal are arranged on the substrate; the conductive line is electrically connected with the control bare die and/or the wiring terminal and/or the light-emitting bare die; the control bare die is configured to control a switch and/or current of the light-emitting bare die; and the wiring terminal is externally connected with a power supply.

2. The light-emitting device according to claim 1, wherein a length of the substrate is a, a width of the substrate is b, and a length-width ratio a/b≥5.

3. The light-emitting device according to claim 1, wherein the control bare die is MCU bare die or decoding bare die.

4. The light-emitting device according to claim 1, wherein a current limiting resistor is connected in series between the control bare die and the wiring terminal and/or between the control bare die and the light-emitting bare die.

5. The light-emitting device according to claim 1, wherein the light-emitting bare die is connected in parallel with a zener diode.

6. The light-emitting device according to claim 1, wherein the light-emitting bare die is a monochrome bare die or a polychrome bare die.

7. The light-emitting device according to claim 1, wherein the substrate is coated with a transparent medium layer and/or a transparent medium layer containing phosphor powder.

8. The light-emitting device according to claim 1, wherein the conductive line is a silver paste conductive line.

9. The light-emitting device according to claim 1, wherein the substrate is a transparent substrate.

10. A bulb, comprising the light-emitting device according to claim 1.

11. A manufacturing process of a light-emitting device, wherein the manufacturing process comprises:
1) wiring: arranging a conductive line and a wiring terminal on a substrate;
2) die bonding: placing a control bare die and a light-emitting bare die on the substrate;
3) welding wire: connecting the control bare die and the light-emitting bare die to the conductive line and the wiring terminal.

12. The manufacturing process of the light-emitting device according to claim 11, wherein the substrate in step 1) is a transparent substrate.

13. The manufacturing process of the light-emitting device according to claim 11, wherein the conductive line set in step 1) is formed by printing silver paste on the substrate and then sintering.

14. The manufacturing process of the light-emitting device according to claim 11, wherein a specification of the substrate in step 1) is: a length is a, a width is b, and a length-width ratio a/b≥5.

15. The manufacturing process of the light-emitting device according to claim 11, wherein the step 2) die bonding further comprises: placing a current limiting resistor on the substrate; the step 3) welding wire further comprises: connecting the current limiting resistor to the conductive line and the wiring terminal and/or connecting the current limiting resistor to the control bare die and the light-emitting bare die.

16. The manufacturing process of the light-emitting device according to claim 11, wherein the step 2) die bonding further comprises: placing a zener diode on the substrate; the welding wire in step 3) further comprises: connecting the zener diode to the conductive line.

17. The manufacturing process of the light-emitting device according to claim 11, wherein the control bare die is the decoding bare die or the MCU bare die.

18. The manufacturing process of the light-emitting device according to claim 11, wherein the light-emitting bare die is a monochrome bare die or a polychrome bare die.

19. The manufacturing process of the light-emitting device according to claim 11, wherein the manufacturing process further comprises: 4) gluing: coating a transparent medium layer and/or a transparent medium layer containing phosphor powder on the light-emitting device obtained in step 3).
